(19) United States
(12) Patent Application Publication
(10) Pub. No.: US 2010/0252867 A1
(43) Pub. Date: Oct. 7, 2010

(54) MFMS-FET, Ferroelectric Memory Device, And Methods Of Manufacturing The Same

(75) Inventor: Byung-Eun PARK, Seoul (KR)

Correspondence Address: SEAN LIAM KELLEHER;Kelleher IP PLLC, 16 PECKSLIP RD, CARMEL, NY, 10512, US

(73) Assignee: University of Seoul, Seoul (KR)

(21) Appl. No.: 12/739,953

(22) PCT Filed: Oct. 27, 2008
(86) PCT No.: PCT/KR2008/006326

§ 371 Date: Apr. 26, 2010

(30) Foreign Application Priority Data
Oct. 26, 2007 (KR) 10-2007-0108508
Oct. 27, 2008 (KR) 10-2008-0105121

(51) Int. Cl. H01L 27/105; H01L 21/8232; H01L 21/338

(52) U.S. Cl. 257/272; 438/171; 257/E21.615; 257/E21.45; 257/E27.081

(57) ABSTRACT

Disclosed herein are a metal-ferroelectric-metal-substrate (MFMS) field-effect transistor (FET), an MFMS-ferroelectric memory device, and method of manufacturing the same. The MFMS-FET and the ferroelectric memory device in accordance with the present invention include: a substrate including source and drain regions, and a channel region formed therebetween; a buffer layer formed on the top of the channel region of the substrate; a ferroelectric layer formed on the buffer layer; and a gate electrode formed on the ferroelectric layer, wherein the buffer layer is formed of a conductive material.

### TECHNICAL FIELD

The present invention relates to a metal-ferroelectric-metal-substrate (MFMS) field-effect transistor (FET) and a ferroelectric memory device having a simple structure and excellent data retention characteristics.

### BACKGROUND ART

At present, extensive research aimed at realizing a transistor or a memory device using a ferroelectric material has continued to progress. FIG. 1 is a cross-sectional view showing a typical structure of a metal-ferroelectric-semiconductor (MFS) ferroelectric memory device using a ferroelectric material.

As shown in FIG. 1, source and drain regions 2 and 3 are formed in predetermined areas of a silicon substrate 1, and a ferroelectric layer 5 is formed on a channel region 4 between the source and drain regions 2 and 3. In this case, the ferroelectric layer 5 comprises an inorganic material having ferroelectric characteristics such as PbZrₓTi₁₋ₓO₃ (PZT), SrBi₂Ta₂O₉ (SBT), (Bi,La)₄Ti₃O₁₂ (BLT), and the like. Moreover, a source electrode 6, a drain electrode 7, and a gate electrode 8 formed of a metal material, respectively, are arranged on the top of the source and drain regions 2 and 3 and the ferroelectric layer 5.

In the ferroelectric memory having the above-described structure, the ferroelectric layer 5 has polarization characteristics in accordance with a voltage applied through the gate electrode 8, and a conductive channel is formed between the source region 2 and the drain region 3 by the polarization characteristics. As a result, a current flows between the source electrode 6 and the drain electrode 7. Especially, in the above-described structure, even in a case where the voltage applied through the gate electrode 8 is cut off, the polarization characteristics of the ferroelectric layer 5 are continuously maintained. Accordingly, the above-described structure has attracted much attention since it can form a non-volatile memory only with one transistor (1T) even though a capacitor is not provided.

However, the ferroelectric memory having the above-described structure has the following problems. That is, when the ferroelectric layer 5 is directly formed on the silicon substrate 1, a transition layer of low quality is formed on the boundary between the ferroelectric layer 5 and the silicon substrate 1 during the formation of the ferroelectric layer 5, and chemical elements such as Pb and Bi in the ferroelectric layer 5 are diffused into the silicon substrate 1, thus making it difficult to form a ferroelectric layer 5 of high quality. As a result, there occurs a problem that the polarization characteristics of the ferroelectric layer 5 are deteriorated, that is, the data retention time of the ferroelectric memory becomes very short.

In consideration of the above problems, as shown in FIG. 2, a so-called metal-ferroelectric-insulator-semiconductor (MFIS) structure, in which a buffer layer 20 formed mainly of an oxide is provided between the silicon substrate 1 and the ferroelectric layer 5, has been recently proposed.

However, the MFIS type ferroelectric memory has some problems in that, since the buffer layer 20 formed between the ferroelectric layer 5 and the substrate 1 acts as a capacitor, the polarization characteristics of the ferroelectric layer 5 are deteriorated due to a depolarization field caused by the buffer layer 20, thus deteriorating the data retention characteristics.

That is, FIG. 3 is a diagram showing an equivalent circuit in a state where a gate voltage applied to the gate electrode 8 is cut off in the MFIS structure. In FIG. 3, a capacitor C1 corresponds to the ferroelectric layer 5 and a capacitor C2 corresponds to the buffer layer 20. In case of a dielectric layer formed of a dielectric material, if an externally applied voltage is cut off, an inner potential is set to 0. However, the ferroelectric material has a constant polarization value Q due to a spontaneous polarization even in a case where the external voltage is cut off. That is, in the equivalent circuit of FIG. 3, the capacitor C1 corresponding to the ferroelectric layer 5 has a polarization value corresponding to the polarization value Q.

Accordingly, in a closed loop including the capacitors C1 and C2 connected in series, an inverse polarization field is generated in the capacitor C2 to make the potential of the closed loop become 0 in general by offsetting the polarization value Q of the capacitor C1. Since the direction of the inverse polarization field is opposite to that of the polarization field by the capacitor C1, the polarization value Q of the capacitor C1 may be continuously deteriorated.

In the MFIS ferroelectric memory device shown in FIG. 2, the polarization characteristics of the ferroelectric layer 5 are deteriorated due to the depolarization field caused by the buffer layer 20 and thereby the data retention characteristics are degraded. As a result, the data retention time cannot exceed 30 days even in case of an excellent product manufactured in a laboratory.

### DISCLOSURE

### Technical Problem

Accordingly, the present invention has been made in an effort to solve the above-described problems, and an object of the present invention is to provide a field-effect transistor (FET), a ferroelectric memory device, which have a simple structure and excellent data retention characteristics, and methods of manufacturing the same.

### Technical Solution

In accordance with a first aspect of the present invention, there is provided a metal-ferroelectric-metal-substrate (MFMS) ferroelectric memory device comprising: a substrate including source and drain regions, and a channel region formed therebetween; a buffer layer formed on the top of the channel region of the substrate; a ferroelectric layer formed on the buffer layer; and a gate electrode formed on the ferroelectric layer, wherein the buffer layer comprises a conductive material.

In accordance with a second aspect of the present invention, there is provided a metal-ferroelectric-metal-substrate (MFMS) field-effect transistor (FET) comprising: a substrate including source and drain regions, and a channel region formed therebetween; a buffer layer formed on the top of the channel region of the substrate; a ferroelectric layer formed on the buffer layer; and a gate electrode formed on the ferroelectric layer, wherein the buffer layer comprises a conductive material.

The conductive material may comprise a metal.

The conductive material may comprise one selected from the group consisting of a conductive metal oxide, an alloy or compound thereof.

The conductive material may comprise a conductive organic material.

The conductive material may comprise a silicide.

The buffer layer may comprise a multilayer structure.

The ferroelectric layer may comprise at least one selected from the group consisting of a ferroelectric oxide, a polymer ferroelectric, a ferroelectric fluoride, a ferroelectric semiconductor, and a solid solution thereof.

The buffer layer comprises titanium nitride (TiN) and the ferroelectric layer comprises (Bi,La)₄Ti₃O₁₂ (BLT).

The MFMS ferroelectric memory device may further include an insulating layer for shielding the source and drain regions and the buffer layer.

The insulating layer may comprise a ferroelectric material.

In accordance with a third aspect of the present invention, there is provided a method of manufacturing a metal-ferroelectric-metal-substrate (MFMS) ferroelectric memory device, the method comprising: forming source, drain, and channel regions on a substrate; forming a buffer layer of a conductive material in an area corresponding to the channel region of the substrate; forming a ferroelectric layer on the top of the buffer layer; and forming a gate electrode on the top of the ferroelectric layer.

In accordance with a fourth aspect of the present invention, there is provided a method of manufacturing a metal-ferroelectric-metal-substrate (MFMS) field-effect transistor (FET), the method comprising: forming source, drain, and channel regions on a substrate; forming a buffer layer of a conductive material in an area corresponding to the channel region of the substrate; forming a ferroelectric layer on the top of the buffer layer; and forming a gate electrode on the top of the ferroelectric layer.

The method may further comprise the step of forming an insulating layer for shielding the source and drain regions and the buffer layer.

In the step of forming the ferroelectric layer, the ferroelectric layer may be coated on the entire surface of the buffer layer.

### DESCRIPTION OF DRAWINGS

FIG. 1 is a cross-sectional view showing a structure of a conventional metal-ferroelectric-semiconductor (MFS) ferroelectric memory device;

FIG. 2 is a cross-sectional view showing a structure of a conventional metal-ferroelectric-insulator-semiconductor (MFIS) ferroelectric memory device;

FIG. 3 is a diagram illustrating problems of the conventional structure shown in FIG. 2;

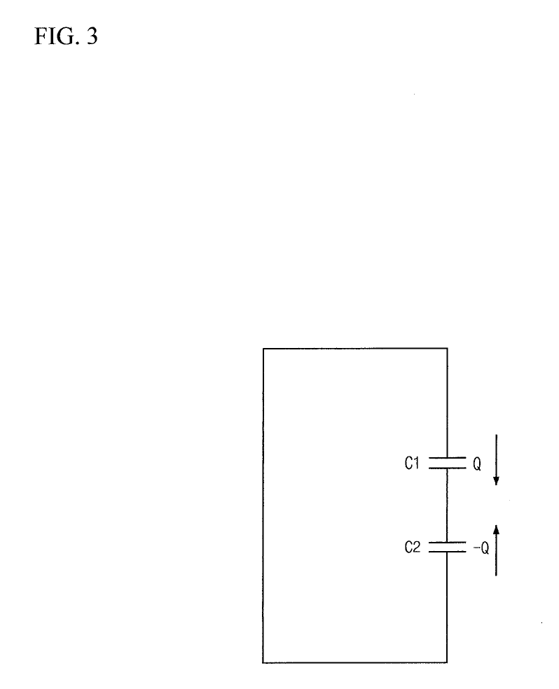

FIG. 4 is a cross-sectional view showing a structure of a field-effect transistor or a ferroelectric memory device having a metal-ferroelectric-metal-substrate (MFMS) structure in accordance with a first embodiment of the present invention;

FIG. 5 is a graph showing ferroelectric characteristics of the MFMS structure in accordance with the present invention;

FIG. 6 is a cross-sectional view showing a structure of a field-effect transistor or a ferroelectric memory device having an MFMS structure in accordance with a second embodiment of the present invention;

FIG. 7 is a cross-sectional view showing a structure of a field-effect transistor or a ferroelectric memory device having an MFMS structure in accordance with a third embodiment of the present invention; and

FIG. 8 is a process diagram illustrating a process of manufacturing a field-effect transistor or a ferroelectric memory device in accordance with the present invention.

### MODE FOR INVENTION

Hereinafter, preferred embodiments in accordance with the present invention will be described with reference to the accompanying drawings. The preferred embodiments are provided so that those skilled in the art can sufficiently understand the present invention, but can be modified in various forms and the scope of the present invention is not limited to the preferred embodiments.

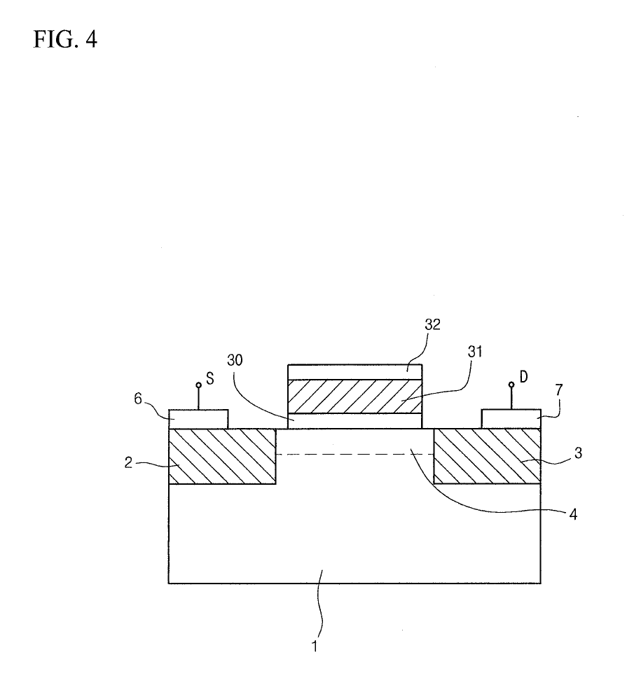

FIG. 4 is a cross-sectional view showing a structure of a field-effect transistor or a ferroelectric memory device in accordance with a first embodiment of the present invention.

The ferroelectric memory device in accordance with the present invention has a metal-ferroelectric-metal-substrate (MFMS) structure, differently from a conventional metal-ferroelectric-semiconductor (MFS) structure and a conventional metal-ferroelectric-insulator-semiconductor (MFIS) structure.

As shown in FIG. 4, source and drain regions 2 and 3 are formed in predetermined areas of a silicon substrate 1, and a buffer layer 30 is formed of a conductive material on a channel region 4 between the source and drain regions 2 and 3.

In this case, the buffer layer 30 may comprise at least one selected from the group consisting of conductive metals such as gold (Au), silver (Ag), aluminum (Al), platinum (Pt), etc., conductive metal oxides such as RuO₂, RuO₂/TiN, SrRuO₃, YBCO, Pt/TiO₂, Pt/IrOₓ, IrOₓ, TiN, ITO, SrTiO₃, etc., alloys or compounds thereof, conductive organics, mixtures or compounds with a conductive polymer as a substrate such as polyaniline, poly(3,4-ethylenedioxythiophene)/poly(styrenesulfonate) (PEDOT/PSS), etc., silicides such as TaSi, TiSi, WSi, NiWSi, PtSi, CoSi, ErSi, and mixtures or compounds of thereof.

Moreover, the buffer layer 30 may comprise a multilayer structure of conductive layers formed of the above-described conductive materials.

A ferroelectric layer 31 is formed on the buffer layer 30. The ferroelectric layer 31 may comprise at least one selected from the group consisting of a ferroelectric oxide having ferroelectric characteristics, a polymer ferroelectric material, a ferroelectric fluoride such as BaMgF₄ (BMF), and a ferroelectric semiconductor.

The ferroelectric oxide may comprise at least one selected from the group consisting of perovskite ferroelectric materials such as PbZrₓTi₁₋ₓO₃ (PZT), BaTiO₃ and PbTiO₃, pseudo-ilmenite ferroelectric materials such as LiNbO₃ and LiTaO₃, tungsten-bronze (TB) ferroelectric materials such as PbNb₃O₆ and Ba₂NaNb₅O₁₅, ferroelectric materials having a bismuth layer structure such as SrBi₂Ta₂O₉ (SBT), (Bi,La)₄Ti₃O₁₂ (BLT) and Bi₄Ti₃O₁₂, pyrochlore ferroelectric materials such as La₂Ti₂O₇, solid solutions thereof, and ferroelectric materials such as RMnO₃, Pb₅Ge₃O₁₁ (PGO) and BiFeO₃ (BFO) including a rare earth element (R) such as Y, Er, Ho, Tm, Yb and Lu.

Moreover, the polymer ferroelectric material may comprise at least one selected from the group consisting of polyvinylidene fluoride (PVDF), PVDF polymer, PVDF copolymer, PVDF terpolymer and, further, odd-numbered nylon, cyano-polymer, and polymer or copolymer thereof. Preferably, the ferroelectric layer 31 comprises PVDF having a β-phase crystal structure.

Furthermore, the ferroelectric semiconductor comprises at least one selected from the group consisting of 2-6 compounds such as CdZnTe, CdZnS, CdZnSe, CdMnS, CdFeS, CdMnSe and CdFeSe.

In addition, the ferroelectric layer 31 may comprise a mixture of ferroelectric materials. For example, a mixture of an inorganic ferroelectric material and an organic ferroelectric material, a mixture of an inorganic ferroelectric material and an organic material, or a mixture of an inorganic ferroelectric material and a metal may be used.

Next, a gate electrode 32 as an electrode layer for polarizing the ferroelectric layer 31 is formed on the ferroelectric layer 31. The gate electrode 32 may comprise at least one selected from the group consisting of conductive metals including gold (Au), silver (Ag), aluminum (Al), platinum (Pt), etc., conductive metal oxides such as indium tin oxide (ITO), strontiumtitanate (SrTiO₃), etc., alloys or compounds thereof, conductive organics, and mixtures or compounds with a conductive polymer as a substrate such as polyaniline, poly(3,4-ethylenedioxythiophene)/poly(styrenesulfonate) (PEDOT/PSS).

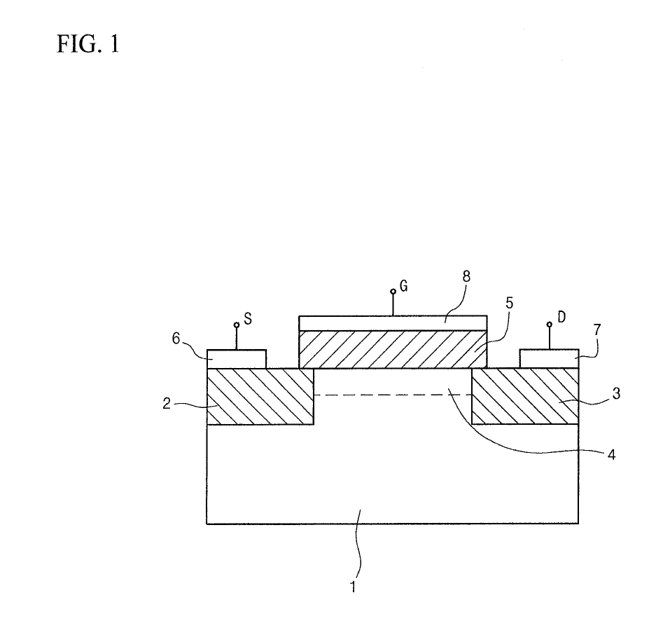

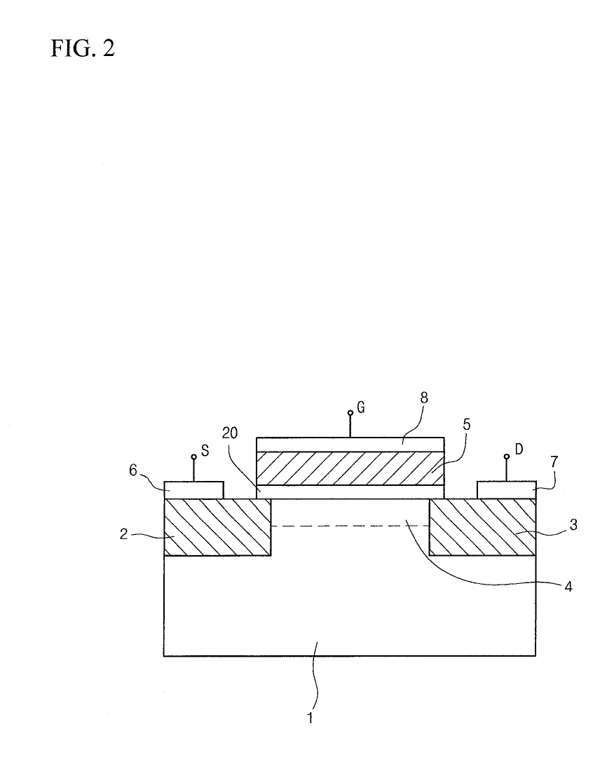

In the above-described structure, the polarization is generated in the ferroelectric layer 31 by applying a predetermined voltage through the gate electrode 32 in the same manner as the conventional ferroelectric memory devices shown in FIGS. 1 and 2.

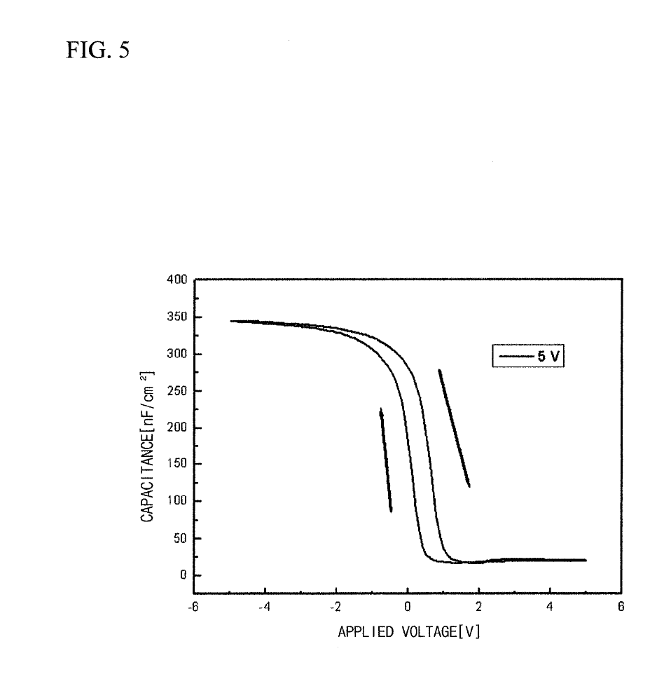

FIG. 5 is a characteristic graph showing the change in capacitance value of the ferroelectric layer 31 in accordance with the gate voltage, in which the change was measured after a TiN layer was formed to a thickness of 80 nm as the buffer layer of FIG. 4 and a BLT layer was formed to a thickness of 300 nm as the ferroelectric layer 31.

It can be seen from FIG. 5 that the capacitance value of the ferroelectric layer 31 shows hysteretic characteristics in accordance with the change in the gate voltage in the structure of FIG. 4.

Like this, when the polarization is generated in the ferroelectric layer 31, a channel is formed or not in the channel region 4 between the source region 2 and the drain region 3 based on the polarization characteristics. As a result, it functions as a transistor in which the current flow between the source region 2 and the drain region 3 is generated or cut off according to whether or not the channel is formed.

In a case where a memory cell or a memory cell array is formed using the above-described transistor, a predetermined voltage is applied to a drain electrode 7 and, at the same time, in a state where a source electrode 6 is grounded, it is determined whether data stored in the corresponding memory cell is “1” or “0” based on whether or not the transistor is in a conductive state.

Accordingly, with the above-described one-transistor (1T) structure, it is possible to form one memory cell.

In the above-described structure, the ferroelectric layer 31 is not directly in contact with the silicon substrate 1 but connected thereto through the buffer layer 30. Accordingly, it is possible to prevent a transition layer of low quality from being formed on the boundary between the ferroelectric layer 5 and the silicon substrate 1 during the formation of the ferroelectric layer 5.

Moreover, the buffer layer 30 is formed of a conductive material. Accordingly, since the depolarization field caused by the buffer layer 20 in the conventional structure shown in FIG. 2 is removed, it is possible to prevent the data retention characteristics from being degraded due to the deterioration of the polarization characteristics caused by the depolarization field.

Moreover, the structure of the memory device or the transistor in accordance with the present invention can be modified in various ways as long as the MFMS structure is maintained.

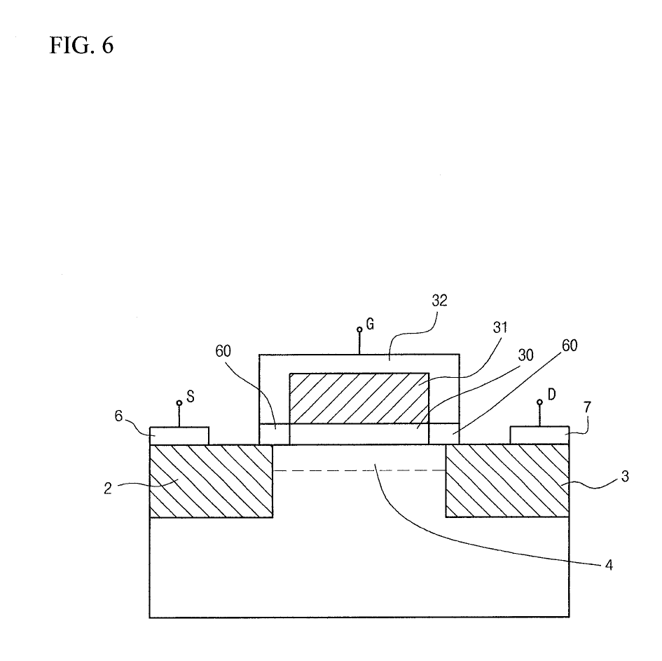

FIG. 6 is a cross-sectional view showing a structure of a field-effect transistor or a ferroelectric memory device in accordance with a second embodiment of the present invention.

In the structure of FIG. 6, like the first embodiment of FIG. 4, source and drain regions 2 and 3 are formed on a silicon substrate 1, and a buffer layer 30 is formed of a conductive material on a channel region 4 between the source and drain regions 2 and 3.

In the present embodiment, an insulating layer 60 surrounding both sides of the buffer layer 30 is formed. The insulating layer 50 is formed of an insulating material such as LaZrO₃, ZrO₂, SiO₂, etc. The insulating layer 60 prevents a current path from being formed between the buffer layer 30, formed of a conductive material, and the source and drain regions 2 and 3.

A ferroelectric layer 31 is formed on the buffer layer 30, and a gate electrode 32 is coated on the entire surface of the ferroelectric layer 31. And, since the other elements are substantially the same as those in the configuration of FIG. 4, the same elements as those of FIG. 4 are denoted by the same reference numerals, and their detailed descriptions will be omitted.

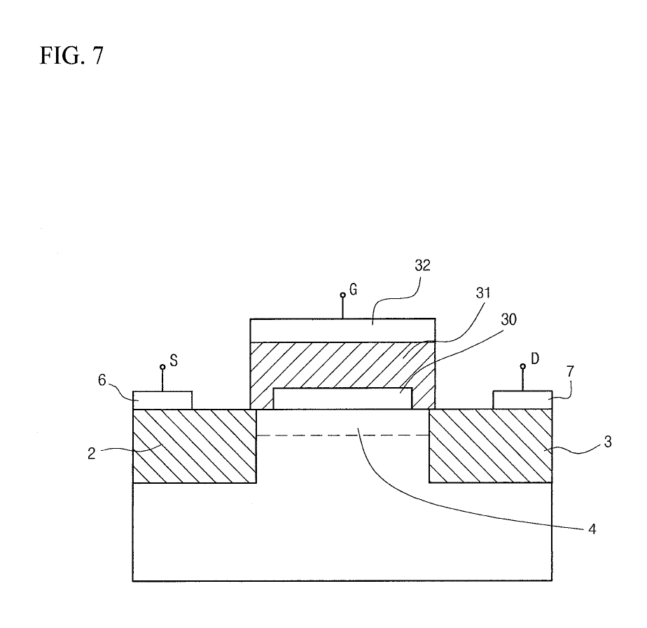

FIG. 7 is a cross-sectional view showing a structure of a field-effect transistor or a ferroelectric memory device in accordance with a third embodiment of the present invention.

In FIG. 7, when a ferroelectric layer 31 is formed on a buffer layer 30, the ferroelectric layer 31 is coated on the entire surface of the buffer layer 30 so that the buffer layer 30 and source and drain regions 2 and 3 are shielded by the ferroelectric layer 31. And, since the other elements are substantially the same as those in the configuration of FIG. 6, the same elements as those of FIG. 6 are denoted by the same reference numerals, and their detailed descriptions will be omitted.

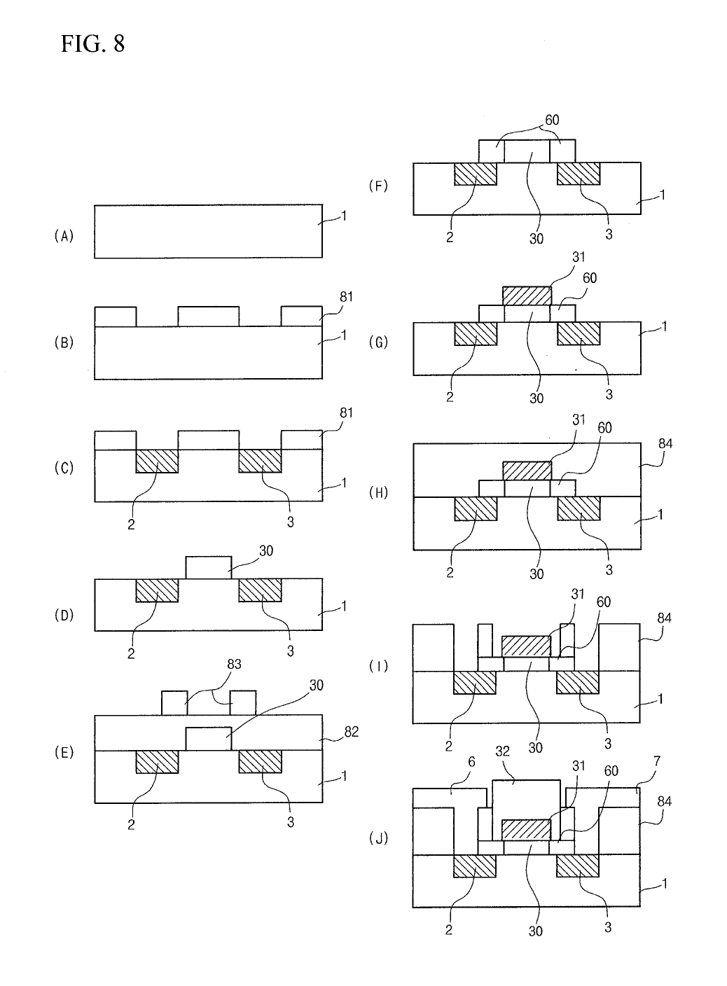

Meanwhile, FIG. 8 shows a process of manufacturing a field-effect transistor or a ferroelectric memory device in accordance with the present invention, which particularly shows a process of manufacturing the structure of FIG. 6.

First, a photoresist 81 is deposited on a substrate 1, and source and drain regions 2 and 3 are formed on the substrate by performing ion implantation using the photoresist 81 as a mask (FIGS. 8A to 8C). Next, a buffer layer 30 is formed of a conductive material on the top of a channel region between the source and drain regions 2 and 3 by sputtering or vacuum deposition (FIG. 8D).

An insulating material layer 82 is formed of SiO₂ on the entire surface of the top of the structure of FIG. 8D (FIG. 8E), etched using a photoresist 83, and then planarized, thus forming a buffer layer 60 (FIG. 8F).

Subsequently, a ferroelectric layer 31 is formed on the top of the buffer layer 30 by an ordinary method such as sputtering or vacuum deposition (FIG. 8G).

An insulating layer 84 is coated on the entire top surface of the structure of FIG. 8G (FIG. 8H), penetration holes are formed on the top of the source and drain regions 2 and 3 and the ferroelectric layer 31 (FIG. 8I), and then a source electrode 6, a drain electrode 7, and a gate electrode 32 are formed (FIG. 8J), thus obtaining a field-effect transistor or a ferroelectric memory device.

As above, exemplary embodiments of the present invention have been described; however, the present invention is not limited to these embodiments but various modifications are possible within the scope of the invention.

For example, although the silicon substrate is used as the substrate 1 in the above embodiments, it is possible to use any material and structure, which can form a channel between the source region 2 and the drain region 3 by an external electric field, as the substrate 1.

### INDUSTRIAL APPLICABILITY

As described above, according to the present invention, it is possible to realize a ferroelectric memory device having a simple structure and excellent data retention characteristics and capable of forming a non-volatile memory cell with a 1T structure.

1. A metal-ferroelectric-metal-substrate (MFMS) ferroelectric memory device comprising:
a substrate including source and drain regions, and a channel region formed therebetween;
a buffer layer formed on the top of the channel region of the substrate;
a ferroelectric layer formed on the buffer layer; and
a gate electrode formed on the ferroelectric layer,
wherein the buffer layer comprises a conductive material.

2. The MFMS ferroelectric memory device of claim 1, wherein the conductive material comprises a metal.

3. The MFMS ferroelectric memory device of claim 1, wherein the conductive material comprises one selected from the group consisting of a conductive metal oxide, an alloy or compound thereof.

4. The MFMS ferroelectric memory device of claim 1, wherein the conductive material comprises a conductive organic material.

5. The MFMS ferroelectric memory device of claim 1, wherein the conductive material comprises a silicide.

6. The MFMS ferroelectric memory device of claim 1, wherein the buffer layer comprises a multilayer structure.

7. The MFMS ferroelectric memory device of claim 1, wherein the ferroelectric layer comprises at least one selected from the group consisting of a ferroelectric oxide, a polymer ferroelectric, a ferroelectric fluoride, a ferroelectric semiconductor, and a solid solution thereof.

8. The MFMS ferroelectric memory device of claim 1, wherein the buffer layer comprises titanium nitride (TiN) and the ferroelectric layer comprises (Bi,La)₄Ti₃O₁₂ (BLT).

9. The MFMS ferroelectric memory device of claim 1, further comprising an insulating layer for shielding the source and drain regions and the buffer layer.

10. The MFMS ferroelectric memory device of claim 9, wherein the insulating layer comprises a ferroelectric material.

11. A metal-ferroelectric-metal-substrate (MFMS) field-effect transistor (FET) comprising:
a substrate including source and drain regions, and a channel region formed therebetween;
a buffer layer formed on the top of the channel region of the substrate;
a ferroelectric layer formed on the buffer layer; and
a gate electrode formed on the ferroelectric layer,
wherein the buffer layer comprises a conductive material.

12. The MFMS-FET of claim 11, wherein the buffer layer comprises a multilayer structure.

13. The MFMS-FET of claim 11, further comprising an insulating layer for shielding the source and drain regions and the buffer layer.

14. The MFMS-FET device of claim 13, wherein the insulating layer comprises a ferroelectric material.

15. The MFMS-FET device of claim 11, wherein the buffer layer comprises titanium nitride (TiN) and the ferroelectric layer comprises (Bi,La)₄Ti₃O₁₂ (BLT).

16. A method of manufacturing a metal-ferroelectric-metal-substrate (MFMS) ferroelectric memory device, the method comprising:
forming source, drain, and channel regions on a substrate;
forming a buffer layer of a conductive material in an area corresponding to the channel region of the substrate;
forming a ferroelectric layer on the top of the buffer layer; and
forming a gate electrode on the top of the ferroelectric layer.

17. The method of claim 16, further comprising forming an insulating layer for shielding the source and drain regions and the buffer layer.

18. The method of claim 16, wherein, in forming the ferroelectric layer, the ferroelectric layer is coated on the entire surface of the buffer layer.

19. A method of manufacturing a metal-ferroelectric-metal-substrate (MFMS) field-effect transistor (FET), the method comprising:
forming source, drain, and channel regions on a substrate;
forming a buffer layer of a conductive material in an area corresponding to the channel region of the substrate;
forming a ferroelectric layer on the top of the buffer layer; and
forming a gate electrode on the top of the ferroelectric layer.

20. The method of claim 19, further comprising forming an insulating layer for shielding the source and drain regions and the buffer layer.
